(19) United States
(12) Patent Application Publication
(10) Pub. No.: US 2022/0410550 A1
(43) Pub. Date: Dec. 29, 2022

(54) TRANSFER METHOD OF DEVICES

(71) Applicant: INDUSTRIAL TECHNOLOGY RESEARCH INSTITUTE, Hsinchu (TW)

(72) Inventors: Pei-Chi CHIEN, Zhudong Township (TW); Chun-Chen CHIANG, Hsinchu City (TW); Ping-Chen CHEN, Zhubei City (TW); Hsien-Kuang LIN, Hsinchu City (TW)

(73) Assignee: INDUSTRIAL TECHNOLOGY RESEARCH INSTITUTE, Hsinchu (TW)

(21) Appl. No.: 17/896,582

(22) Filed: Aug. 26, 2022

Related U.S. Application Data
(62) Division of application No. 16/717,194, filed on Dec. 17, 2019.

(30) Foreign Application Priority Data
Apr. 12, 2019 (TW) 108112811

(51) Int. Cl. B32B 37/00; H01L 21/683

(52) U.S. Cl. CPC B32B 37/025; H01L 21/6835; B32B 2457/00; H01L 2221/68381; H01L 2221/68368; B32B 17/10

(57) ABSTRACT

An adhesive structure is provided, which includes a plastic substrate, and an adhesive layer on the plastic substrate. The adhesive layer includes a releasable adhesive. The adhesive layer has a Young's modulus of 5 MPa to 14 MPa and an adhesive force to glass of 200 gf/25 mm to 2000 gf/25 mm. The adhesive structure can be used to transfer a device.

### CROSS REFERENCE TO RELATED APPLICATIONS

This application is a Divisional of pending U.S. patent application Ser. No. 16/717,194, filed on Dec. 17, 2019 and entitled “METAL-CERAMIC COMPOSITE MATERIAL AND METHOD FOR FORMING THE SAME”, which claims priority from, Taiwan Application Serial Number 108112811, filed on Apr. 12, 2019, the disclosure of which is hereby incorporated by reference herein in its entirety.

### TECHNICAL FIELD

The technical field relates to an adhesive structure, and in particular it relates to a method of transferring devices.

### BACKGROUND

In the process of transferring micro-LEDs en masse, devices can easily sink into an adhesive layer, after which it is difficult to take them out due to their small size and the softness of the adhesive layer. On the other hand, an adhesive structure with a plastic substrate may shift during attachment, which may negatively impact the yield of the product. Accordingly, a novel adhesive structure is called for to overcome these issues.

### SUMMARY

One embodiment of the disclosure provides an adhesive structure, including a plastic substrate and an adhesive layer on the plastic substrate. The adhesive layer includes a releasable adhesive, and the adhesive layer has a Young's modulus of 5 MPa to 14 MPa and an adhesive force to glass of 200 gf/25 mm to 2000 gf/25 mm.

In some embodiments, the adhesive layer after de-adhesion has an adhesive force of less than or equal to 30 gf/25 mm.

In some embodiments, the adhesive layer after de-adhesion has an adhesive force of less than or equal to 20 gf/25 mm.

In some embodiments, the adhesive layer after de-adhesion has an adhesive force of less than or equal to 10 gf/25 mm.

In some embodiments, the adhesive layer has a thickness of less than 10 μm.

In some embodiments, the adhesive layer has a thickness of 1 μm to 9 μm.

In some embodiments, the adhesive structure further includes a glass substrate attached to the plastic substrate through a bonding layer, and the plastic substrate is disposed between the adhesive layer and the bonding layer.

In some embodiments, the plastic substrate comprises polypropylene, polyethylene, polyamide, polyethylene terephthalate, polyvinyl chloride, polyvinyl alcohol, or a copolymer thereof, and the copolymer includes polyolefin or ethylene vinyl acetate.

One of the embodiments of the disclosure provides a method of transferring devices, including: providing a first substrate with a plurality of micro devices having pitches being a predetermined value in a first direction and a second direction, wherein the first substrate and the micro devices have a first adhesive layer between them; transferring the micro devices to a second substrate by contacting the second substrate with the micro devices on the first substrate and de-adhering the first adhesive layer, wherein the surface of the second substrate has a second adhesive layer, wherein the first adhesive layer before de-adhesion has a Young's modulus of 5 MPa to 14 MPa and an adhesive force to glass of 200 gf/25 mm to 2000 gf25 mm.

In some embodiments, the first adhesive layer after de-adhesion has an adhesive force to glass of less than or equal to 30 gf/25 mm.

In some embodiments, the first adhesive layer after de-adhesion has an adhesive force to glass of less than or equal to 20 gf/25 mm.

In some embodiments, the first adhesive layer after de-adhesion has an adhesive force to glass of less than or equal to 10 gf/25 mm.

In some embodiments, the first adhesive layer has a thickness of less than 10 μm.

In some embodiments, the first adhesive layer has a thickness of 1 μm to 9 μm.

In some embodiments, the first adhesive layer after transferring the micro devices has a depth after structure removal, and the depth after structure removal and the structure height of the micro devices have a height ratio of 1:1 to 0.01:1.

In some embodiments, the first adhesive layer after transferring the micro devices has a depth after structure removal, and the depth after structure removal and the structure height of the micro devices have a height ratio of 0.8:1 to 0.05:1.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIGS. 1A to 1F are schematic diagrams illustrating a process for transferring devices according to a first embodiment of the disclosure.

FIG. 2A is a schematic diagram illustrating a roller used in the first embodiment.

FIG. 2B is a schematic diagram illustrating another roller used in the first embodiment.

FIG. 2C is a schematic diagram illustrating another roller used in the first embodiment.

FIGS. 3A to 3F are schematic diagrams illustrating a process for transferring devices according to a second embodiment of the disclosure.

FIG. 4A is a schematic diagram illustrating a first roller used in the second embodiment.

FIG. 4B is a schematic diagram illustrating another first roller used in the second embodiment.

FIG. 4C is a schematic diagram illustrating a second roller used in the second embodiment.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

One embodiment of the disclosure provides an adhesive structure, including a plastic substrate and an adhesive layer on the plastic substrate. The adhesive layer includes a releasable adhesive. The adhesive layer has a Young's modulus of 5 MPa to 14 MPa and an adhesive force to glass of 200 gf/25 mm to 2000 gf/25 mm. In general, the adhesive agent can be coated onto the substrate, and then heated to a temperature higher than 100° C. for a while (e.g. 5 minutes), and then left at room temperature to mature for a period (e.g. 7 days), until the adhesive agent has the above properties. Subsequently, the adhesive layer can be attached to another substrate with micro structures, thereby transferring the micro structures from the other substrate to the adhesive layer. Thereafter, another adhesive layer of a further substrate is attached to the adhesive layer with the micro structures therein, and the adhesive layer is then irradiated by UV to photo cure the adhesive layer (e.g. so-called de-adhesion), thereby greatly lowering the adhesion force of the adhesive layer. As such, the micro structures are transferred to the other adhesive layer of the further substrate. During the transfer process, if the Young's modulus of the adhesive layer is too low, the adhesive layer will be too soft and the micro structures will sink into the adhesive layer, and it will be difficult to take off the micro structures. If the Young's modulus of the adhesive layer is too high, the adhesive layer will be too hard to attach other objects, which may result in insufficient adhesion force and it cannot adhere to the micro structures or pick up the micro structures from the other substrate. If the adhesion force of the adhesive layer to the glass is too high, the adhesive layer may adhere to another substrate, thereby causing adhesive residue. In this embodiment, the adhesive layer after de-adhesion has an adhesion force to the glass of less than or equal to 30 gf/25 mm, such as less than or equal to 20 gf/25 mm, or less than or equal to 10 gf/25 mm. If the adhesion force to the glass of the adhesive layer after de-adhesion is too high, the micro structures cannot be transferred to the further substrate, or some adhesive layer will be remained on the transferred micro structures (adhesive residue). In some embodiments, the adhesive layer has a thickness of less than 10 μm, such as 1 μm to 9 μm. If the adhesive layer is too thick, the depth of the micro structures sunk into the adhesive layer during the attachment will be possibly increased, and it may be difficult to remove the micro structures from the adhesive layer.

In some embodiments, the adhesive structure further includes a glass substrate attached to the plastic substrate through a bonding layer, and the plastic substrate is disposed between the adhesive layer and the bonding layer. For example, the plastic substrate includes polypropylene (PP), polyethylene (PE), polyamide (PA), polyethylene terephthalate (PET), polyvinyl chloride (PVC), polyvinyl alcohol (PVA), the like, or a copolymer thereof such as polyolefin (PO) or ethylene vinyl acetate (EVA). In one embodiment, the bonding layer can be a general commercially available bonding agent, which has a similar property before and after de-adhesion of the adhesive layer. The bonding layer is mainly used to fix the plastic substrate onto the glass substrate. In other words, the adhesive structure is a four layered structure, which sequentially includes the glass substrate, the bonding layer, the plastic substrate, and the adhesive layer. The four layered adhesive structure has better mechanical properties than the two layered adhesive structure (e.g. the plastic substrate and the adhesive layer), allowing it to mitigate the position shift phenomenon (which can easily occur in the adhesive layer of the two layered adhesive structure). This helps improve the yield of the final product.

The adhesive layer can be used as a UV release film for transferring micro structures (e.g. micro-LED). For example, a method of transferring devices includes providing a first substrate with a plurality of micro devices having pitches being a predetermined value in a first direction and a second direction. The first substrate and the micro devices have a first adhesive layer between them. Transferring the micro devices to a second substrate by contacting the second substrate with the micro devices on the first substrate. The surface of the second substrate has a second adhesive layer, wherein the first adhesive layer before de-adhesion has a Young's modulus of 5 MPa to 14 MPa and an adhesive force to glass of 200 gf/25 mm to 2000 gf/25 mm. In some embodiments, the first adhesive layer after de-adhesion has an adhesion force less than or equal to 30 gf/25 mm, such as less than or equal to 20 gf25 mm, or less than or equal to 10 gf/25 mm. In some embodiments, the first adhesive layer has a thickness of less than 10 μm, such as 1 μm to 9 μm. In some embodiments, the first adhesive layer after transferring the micro devices has a depth after structure removal, and the depth after structure removal and the structure height of the micro devices have a height ratio of 1:1 to 0.01 to 1, such as 0.8:1 to 0.05:1.

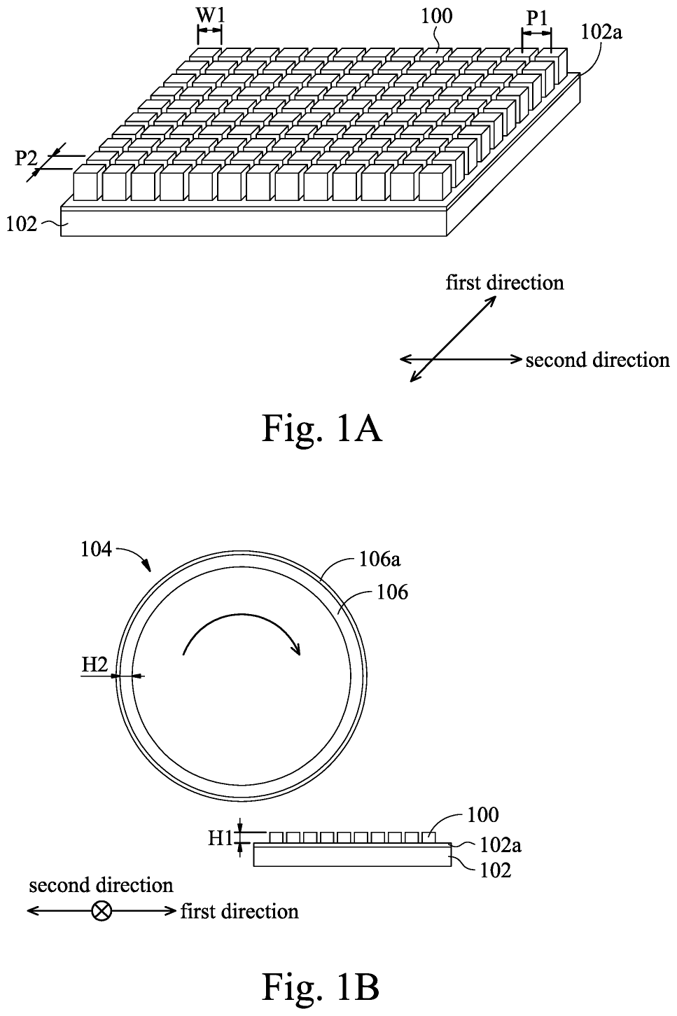

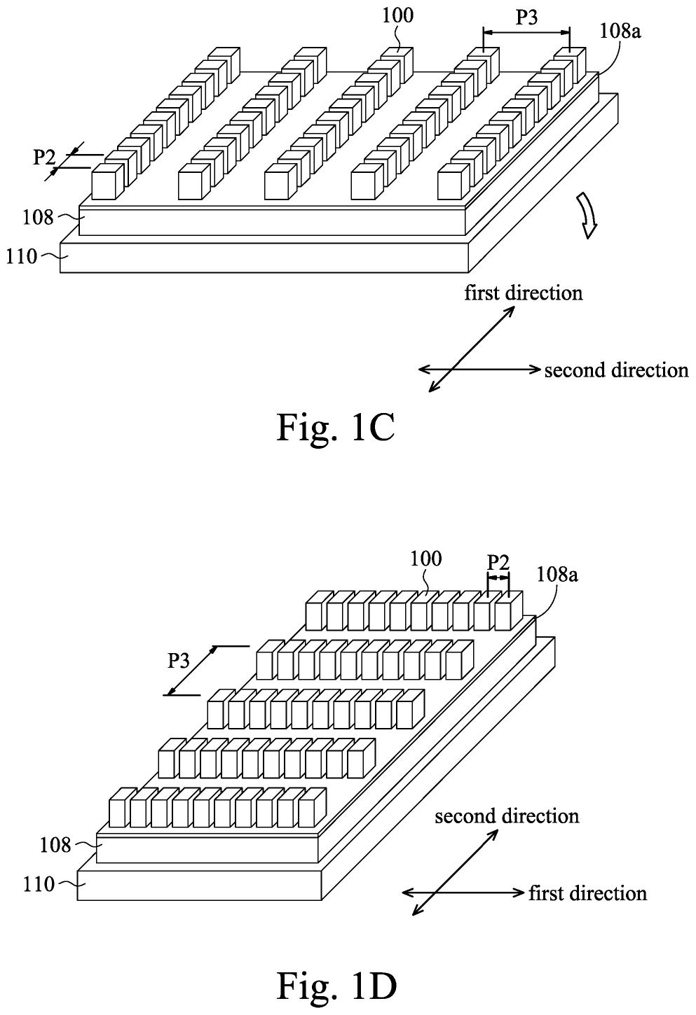

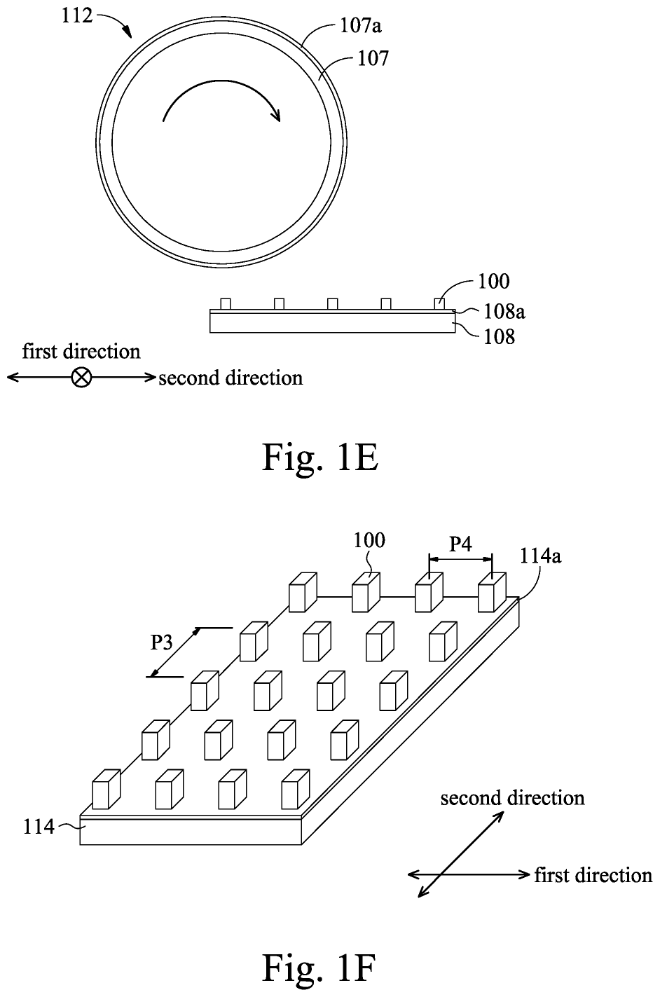

Referring to FIG. 1A, the transfer method for the devices of the present embodiment is applicable to various devices (e.g., a micro device (R/GB) assembly process of a micro LED display), but the disclosure is not limited thereto. Any manufacturing process that requires precise positioning and rapid and mass operations of pitch expansion and the picking and placing of devices may use the method described in the present embodiment. In the present embodiment, a first substrate 102 with a plurality of micro devices 100 is first provided. The material of the first substrate 102 is, for example, a non-deformable inorganic material to reduce variations in the position of the micro devices 100 on the first substrate 102 resulting from variations in the environmental temperature or humidity. Moreover, pitch P1 and pitch P2 of the micro devices 100 on the first substrate 102 in the second direction and the first direction are predetermined values. Herein, “pitch” refers to the distance between central points of two adjacent micro devices 100 in one single direction. Since a gap must be present between the micro devices 100, the pitches P1 and P2 are generally slightly larger than a width W1 of the micro device 100. In addition, in the example of the micro devices of the micro LED display, a method of providing the micro devices 100 may be as follows. A plurality of micro devices of the same color are first simultaneously manufactured on the whole semiconductor substrate. Then, the micro devices are separated by laser cutting or dry etching, for example. Next, the micro devices are transferred onto the first substrate 102, and before the transfer, an adhesive layer 102a is coated on the surface of the first substrate 102 to increase the adhesion force between the first substrate 102 and the micro devices 100. Specifically, the adhesive layer 102a is a pressure-sensitive adhesive such as a UV release film. Therefore, after the pressure-sensitive adhesive is subjected to a light or heat stimulus, a cross-linking reaction occurs or gas is generated, reducing the adhesive force of the pressure-sensitive adhesive. For example, the adhesive force of the UV release film before de-adhesion is greater than the adhesive force after de-adhesion.

Next, referring to FIG. 1B, by rolling a first roller 104 to contact the micro devices 100 on the first substrate 102, the micro devices 100 are transferred to the first roller 104. Specifically, the first roller 104 includes contact line portions 106 radially arranged thereon. An adhesive layer 106a is coated on the surfaces of the contact line portions, and the adhesive layer 106a is a pressure-sensitive adhesive. In the present embodiment, the adhesion force of the adhesive layer 106a is greater than the adhesion force of the adhesive layer 102a after being subjected to a light or heat stimulus, and the adhesion force may be an adhesive force, an electrostatic force, a pressure, or a Van der Waals force. For example, the adhesive layer 106a may use another adhesive material having a viscosity operation window different from that of the adhesive layer 102a to pick up the micro devices 100 on the first substrate 102 by adhesion. One example is a pressure-sensitive adhesive (PSA) having an adhesive force between the adhesive forces of the UV release film before light irradiation (before transfer) and after light irradiation. In one embodiment, the rolling speed of the first roller 104 matches the speed at which the first substrate 102 moves in the extension direction (i.e., the first direction) of the contact line portions 106. This enables mass production.

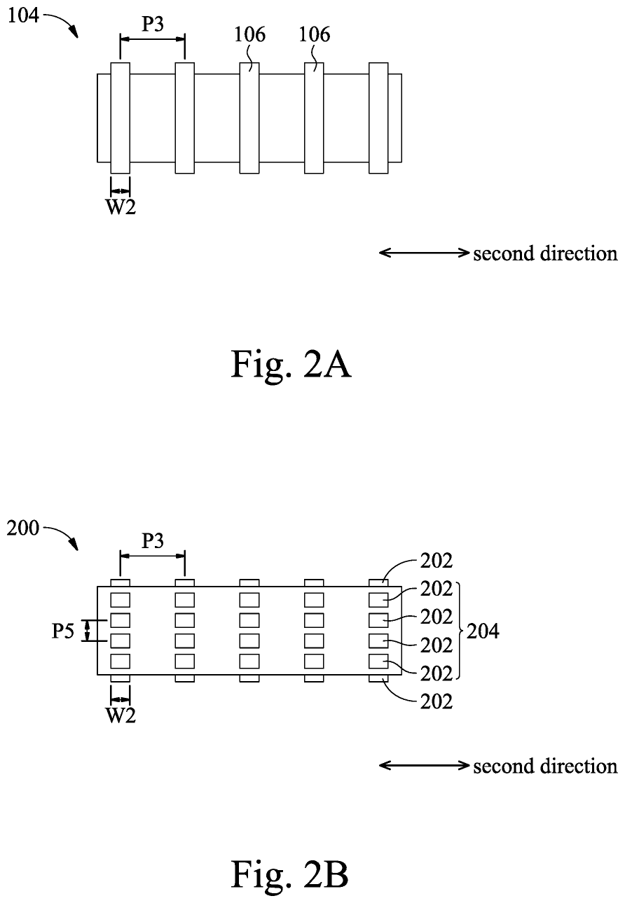

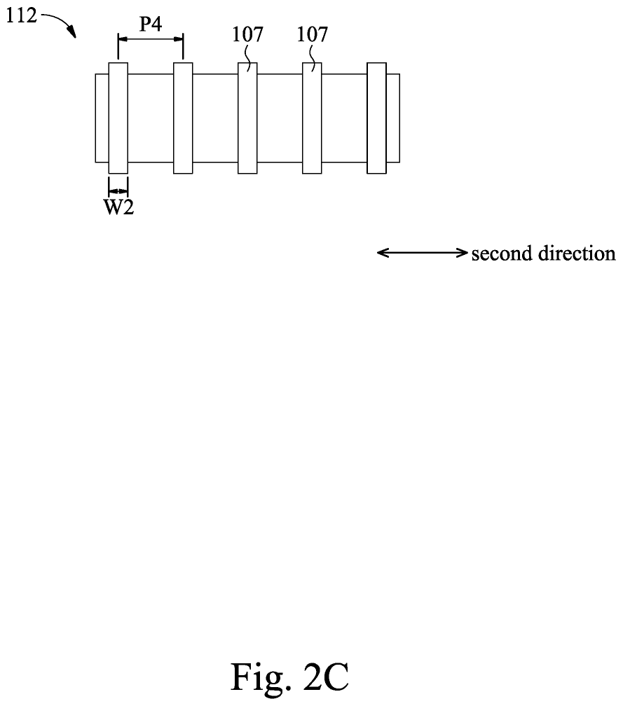

Moreover, since FIG. 1B is a side view in the first direction, only one contact line portion 106 is shown, and the contact line portion 106 is a continuous line. However, in a side view in the second direction (see FIG. 2A), a plurality of contact line portions 106 are observed, and the pitch P3 of the contact line portions 106 is N times P1, namely, N times the predetermined value (N is a positive real number greater than or equal to 1). The width W2 of the contact line portion 106 may be greater than or equal to the width W1 of the micro device 100 to enhance the strength with which the contact line portions 106 pick up or adhere to the micro devices 100. In addition, the height H2 of the contact line portion 106 may be, for example, greater than or equal to the height H1 of the micro device 100 to enhance the operation quality at the moment the contact line portions 106 pick up or adhere to the micro devices 100.

Other modifications may be made to the first roller 104. For example, in a roller 200 shown in FIG. 2B, a contact line portion 204 is formed of a plurality of first protrusions 202. The pitch P5 of the first protrusions 202 is equal to the pitch P2 (i.e., the predetermined value) of the micro devices 100. In other words, when the roller 200 rolls in the first direction and contacts the micro devices 100, each of the micro devices 100 adheres to one of the first protrusions 202.

After the micro devices 100 are transferred to (the contact line portions 106 of) the first roller 104, referring to FIG. 1C, the micro devices 100 of the first roller 104 are transferred to a second substrate 108 (a temporary substrate). An adhesive layer 108a is coated on the surface of the second substrate 108. Specifically, the adhesive layer 108a is a pressure-sensitive adhesive, and the material of the second substrate 108 is selected, for example, to match the coefficient of thermal expansion (CTE) of the first substrate 102. In the present embodiment, the adhesion force of the adhesive layer 108 a is greater than the adhesion force of the adhesive layer 106a, and the adhesion force may be an adhesive force, an electrostatic force, a pressure, or a Van der Waals force. For example, the adhesive layer 108a may use another adhesive material having a viscosity operation window different from that of the adhesive layer 106a to pick up the micro devices 100 on the contact line portions 106 by adhesion. One example is a UV release film, which has an adhesive force before UV light irradiation greater than the adhesive force of the pressure-sensitive adhesive. In FIG. 1C, the pitch P2 in the first direction of the micro devices 100 transferred onto the second substrate 108 is the predetermined value, and the pitch P3 in the second direction is N times P1. Therefore, at this stage, expansion of the pitch of the micro devices 100 by N times in the second direction is completed.

Next, the second substrate 108 is rotated by 90 degrees by using a moving apparatus 110 to obtain the result shown in FIG. 1D. The moving apparatus 110 is not specifically limited herein. Any apparatus capable of rotating the second substrate 108 by 90 degrees is applicable to the disclosure. Therefore, in addition to the plate-shaped apparatus shown in FIG. 1C, a robotic arm, a rotating robot, a linear robot, or a combination of these apparatuses may also be used to complete the operation of rotating the second substrate 108 by 90 degrees.

Then, referring to FIG. 1E, in the present embodiment, a second roller 112 is used to again roll and contact the micro devices 100 on the second substrate 108, wherein the second roller 112 includes contact line portions 107 radially arranged thereon, an adhesive layer 107a is coated on the surfaces of the contact line portions 107, and the adhesive layer 107 a is a pressure-sensitive adhesive. In a side view in the second direction (see FIG. 2C), a plurality of contact line portions 107 are observed, and the pitch P4 of the contact line portions 107 is M times P2, namely, M times the predetermined value (M is a positive real number greater than or equal to 1). Since the second roller 112 rolls in the second direction, only micro devices 100 having a pitch P4 will be transferred to the contact line portions 107 in the first direction. Similar to the first roller 104, the rolling direction of the second roller 112 is not changed in the whole process of the present embodiment. The directions labeled in the drawings represent the arrangement directions of the micro devices 100. Therefore, what is changed is the arrangement direction of the micro devices 100.

In the present embodiment, the adhesion force of the adhesive layer 107a is greater than the adhesion force of the adhesive layer 108a after being subjected to a light or heat stimulus, and the adhesion force may be an adhesive force, an electrostatic force, a pressure, or a Van der Waals force. For example, the adhesive layer 107a may use another adhesive material having a viscosity operation window different from that of the adhesive material of the adhesive layer 108a to pick up the micro devices 100 on the second substrate 108 by adhesion. For example, if the adhesive layer 108a is a UV release film, the adhesive layer 107a may be a pressure-sensitive adhesive having an adhesive force between the adhesive forces of the UV release film before light irradiation (before transfer) and after light irradiation. Through light irradiation to the UV release film, the adhesiveness of the adhesive layer 108a is reduced.

After the micro devices 100 are transferred to (the contact line portions 107 of) the second roller 112, referring to FIG. 1F, the micro devices 100 on the second roller 112 are transferred to a third substrate 114. An adhesive layer 114a is coated on the surface of the third substrate 114. The third substrate 114 may be a temporary substrate or a product substrate. If the third substrate 114 is a temporary substrate, the material is selected, for example, to match the coefficient of thermal expansion (CTE) of the first substrate 102. For example, the first substrate 102 and the third substrate 114 may be formed of the same material. Alternatively, the third substrate 114 is a product substrate having circuits and electrodes. In the present embodiment, the adhesion force of the adhesive layer 114a is greater than the adhesion force of the adhesive layer 107a, and the adhesion force may be an adhesive force, an electrostatic force, a pressure, or a Van der Waals force. For example, when the third substrate 114 is a product substrate having circuits and electrodes, the adhesive layer 114a may be an anisotropic conductive film (ACF) or an anisotropic conductive paste (e.g. self-assembly anisotropic conductive paste, SAP) to simultaneously achieve adhesion, electrical conduction, and self-assembly positioning. On the other hand, if the third substrate 114 is a temporary substrate, the UV release film may be used, and transfer to another product substrate may be performed in a subsequent process. For example, the micro devices 100 on the third substrate 114 may be first attached to a glass substrate, and a UV light is irradiated from the backside of the third substrate 114 to reduce the adhesiveness of the UV release film. Then, the third substrate 114 is peeled off.

In summary of the process of the first embodiment, the apparatus for implementing the first embodiment at least includes the first substrate 102, the first roller 104, the second substrate 108 (i.e., the temporary substrate), the second roller 112, and the moving apparatus 110. Table 1 below shows material selections of the components in the exemplary solution where the transfer of the micro devices is controlled by the adhesive force. However, the disclosure is not limited thereto.

TABLE 1

| component | material | requirement |
|---|---|---|
| first substrate | non-deformable inorganic material, e.g. | reducing variations in position |
| | glass, silicon wafer, quartz | of micro devices thereon |
| | | resulting from variations |
| | | in environmental temperature |
| | | or humidity |
| adhesive layer | UV release film manufactured by Nanya | adhesive force before de- |
| between first | Plastic corporation; glass adhesive force | adhesion being greater than |
| substrate and | before de-adhesion may be adjusted to | adhesive force after de- |
| micro devices | 200 gf/25 mm~2000 gf/25 mm, and adhesion | adhesion |
| | force to glass after de-adhesion may be | |
| | reduced to 30 gf/25 mm or below | |
| first roller | e.g. stainless steel, anodic aluminum oxide | dimensionally stable material |
| | | matching coefficient of |
| | | thermal expansion (CTE) of |
| | | first substrate |
| contact line | polydimethylsiloxane (PDMS) (adhesive | elastomer |
| portion | force: 50 gf/25 mm~100 gf/25 mm) | |
| adhesive layer | pressure-sensitive adhesive (adhesive | adhesive force being between |
| on contact line | force: 100 gf/25 mm~200 gf/25 mm) | adhesive force of UV release |
| portion | | film before light irradiation |
| | | and after light irradiation |
| second | glass, silicon wafer, quartz | transparent, dimensionally |
| substrate | | stable |
| adhesive layer | UV release film as above | adhesive force before de- |
| on second | | adhesion being greater than |
| substrate | | adhesive force of adhesive |
| | | material on contact line |
| | | portions |
| second roller | e.g. stainless steel, anodic aluminum oxide | dimensionally stable materials |
| | | matching coefficient of |
| | | thermal expansion (CTE) of |
| | | second substrate |
| contact line | PDMS | elastomer |
| portions | | |
| adhesive layer | pressure sensitive adhesive | adhesive force being between |
| on contact line | | adhesion force of UV release |
| portions | | film before light irradiation |
| | | and after light irradiation |
| third substrate | product substrate | transparent, flexible, |
| | | dimensionally stable, |
| | glass | transparent, dimensionally |
| | | stable |
| adhesive layer | UV release film as above | adhesive force before de- |
| on third | | adhesion being greater than |
| substrate | | adhesive force of adhesive |
| | | material on contact line |
| | | portions |
| | anisotropic conductive film (ACF) | conductive adhesive for |
| | (peel strength at about 500 gf/25 mm) or | adhesion, electrical |
| | Epowell AP series anisotropic conductive | conduction, and self-assembly |
| | paste (SAP) (peel strength at about | positioning |
| | 4800 gf/25 mm) manufactured by Sekisui | |
| | Chemical Co., Ltd. | |

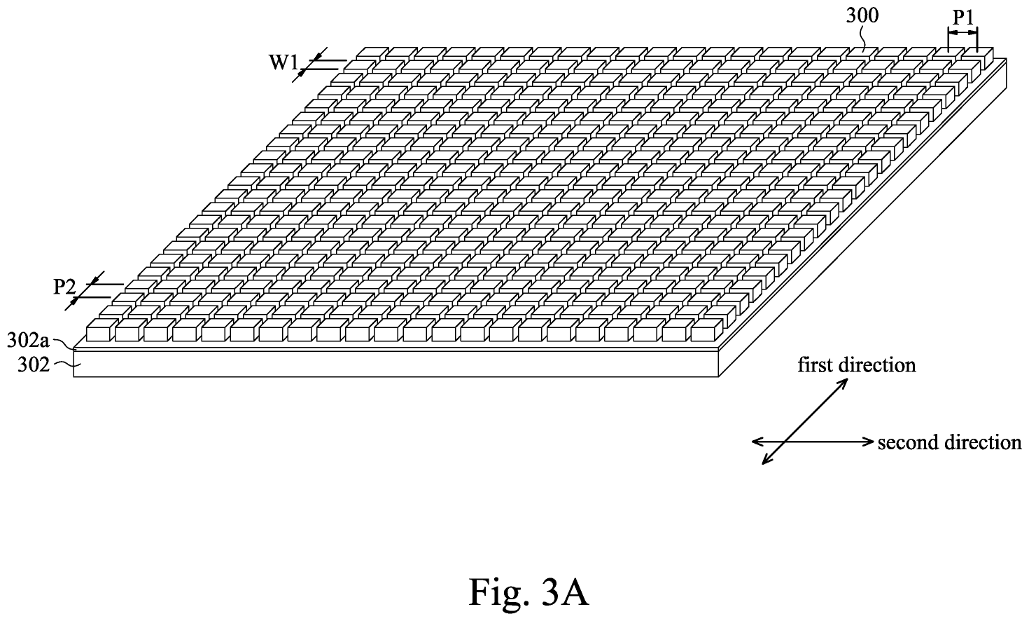

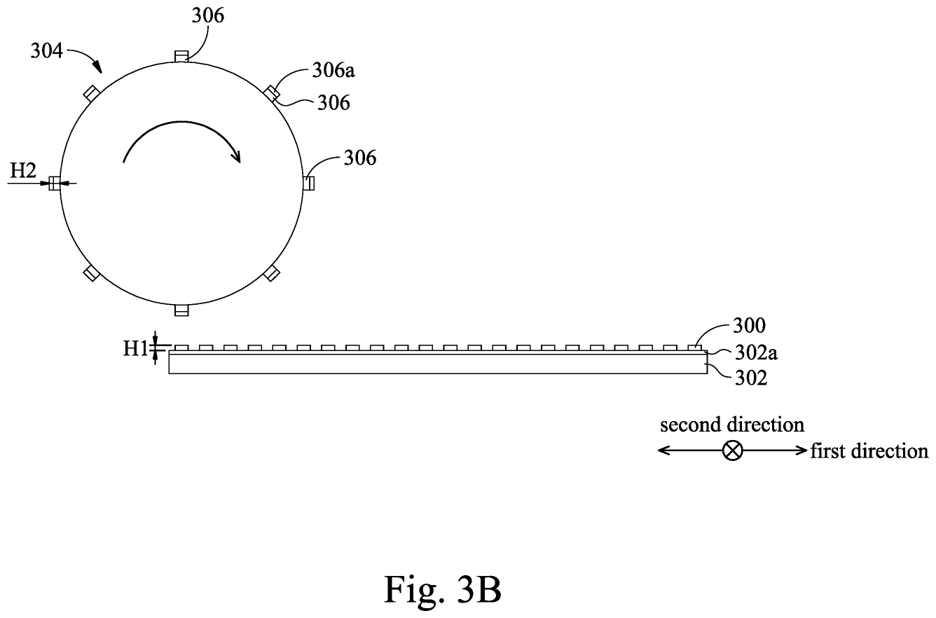

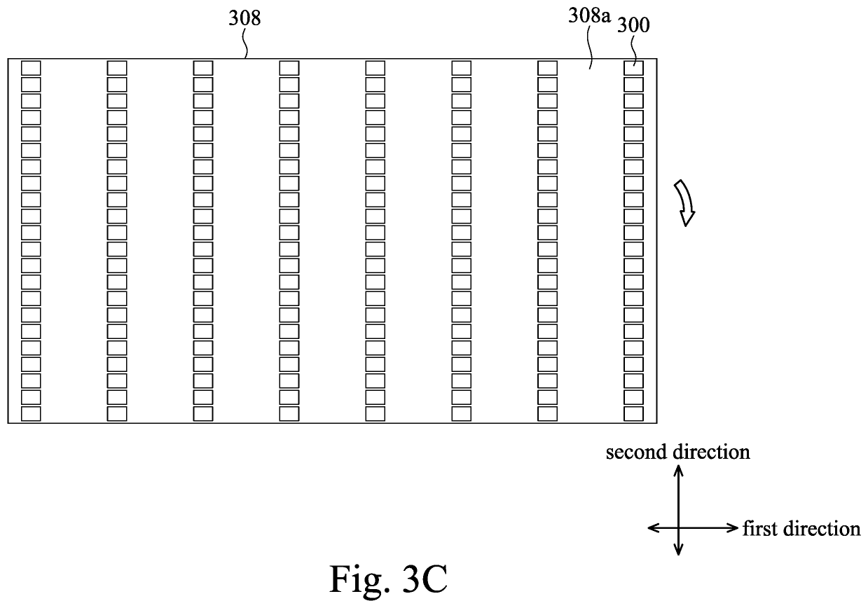

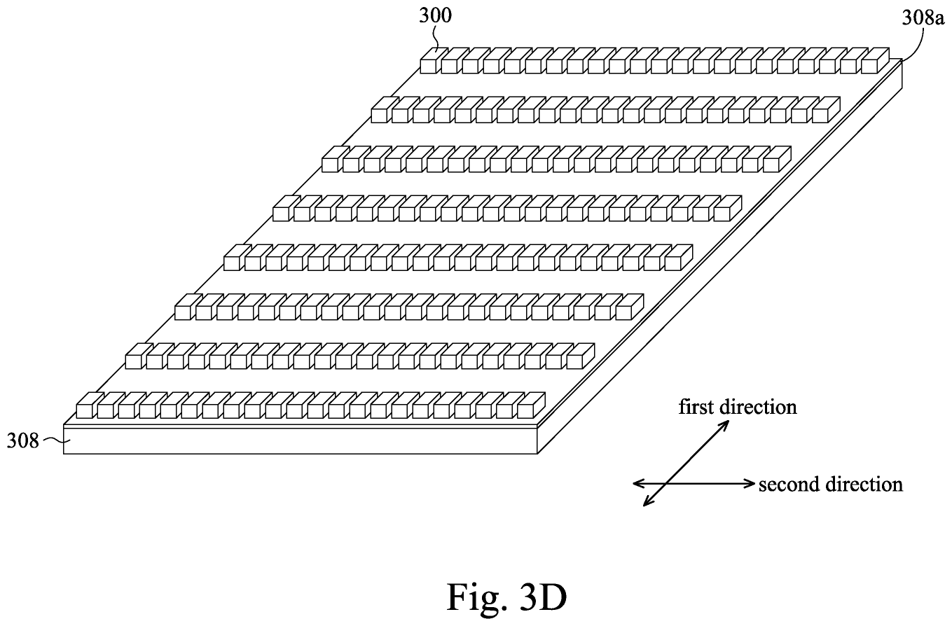

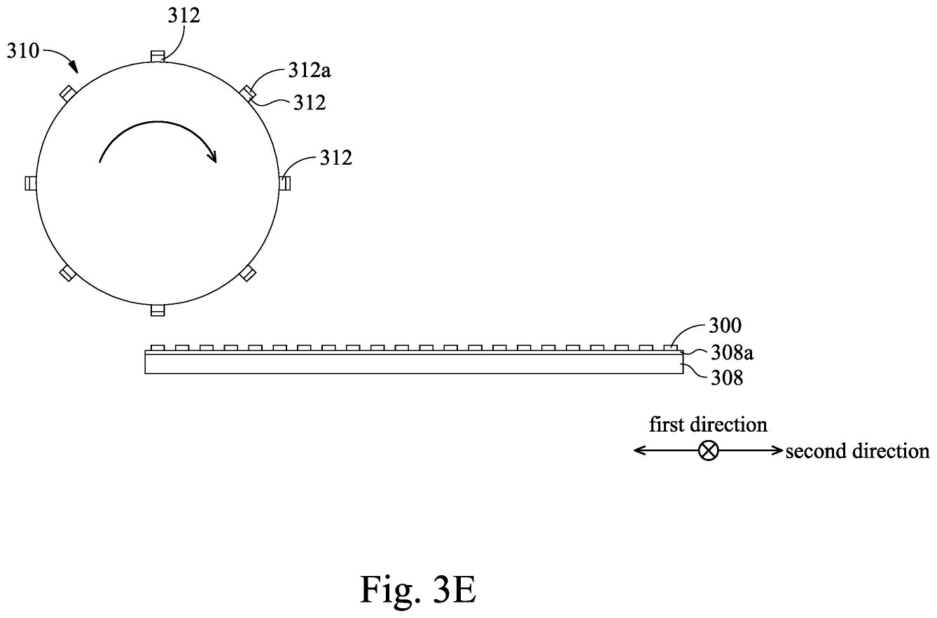

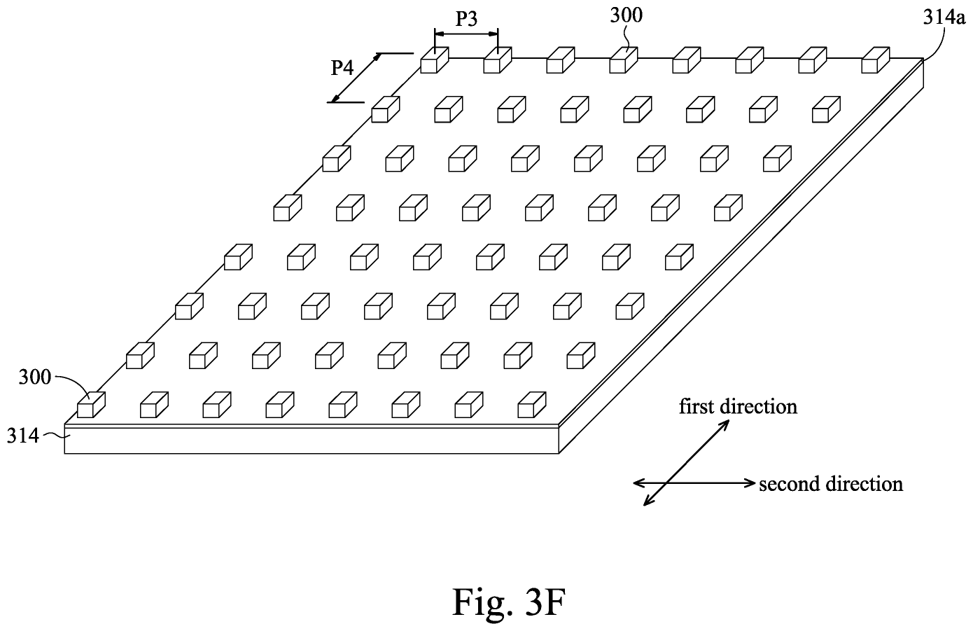

FIGS. 3A to 3F are schematic diagrams illustrating a transfer process for expanding pitches of devices according to a second embodiment of the disclosure.

Referring to FIG. 3A, the transfer method for expanding pitches of devices of the present embodiment is similarly applicable to various manufacturing processes for expanding pitches of devices (e.g., a micro device (R/GB) assembly process of a micro LED display), but the disclosure is not limited thereto. Any manufacturing process that requires precise positioning and rapid and mass operations of pitch expansion and the picking and placing of devices may use the method described in the present embodiment. In the present embodiment, a first substrate 302 with a plurality of micro devices 300 is first provided. An adhesive layer 302a is coated on the surface of the first substrate 302. The material of the first substrate 302 is, for example, a non-deformable inorganic material to reduce variations in the position of the micro devices 300 on the first substrate 302 resulting from variations in the environmental temperature or humidity. Moreover, pitch P1 and pitch P2 of the micro devices 300 on the first substrate 302 in the first direction and the second direction are predetermined values. In addition, the micro devices 300 are thinner than the micro devices of the first embodiment, so the transfer process is more difficult. Reference may be made to the description of the first embodiment for the preparation of the micro devices 300, which shall not be described again here.

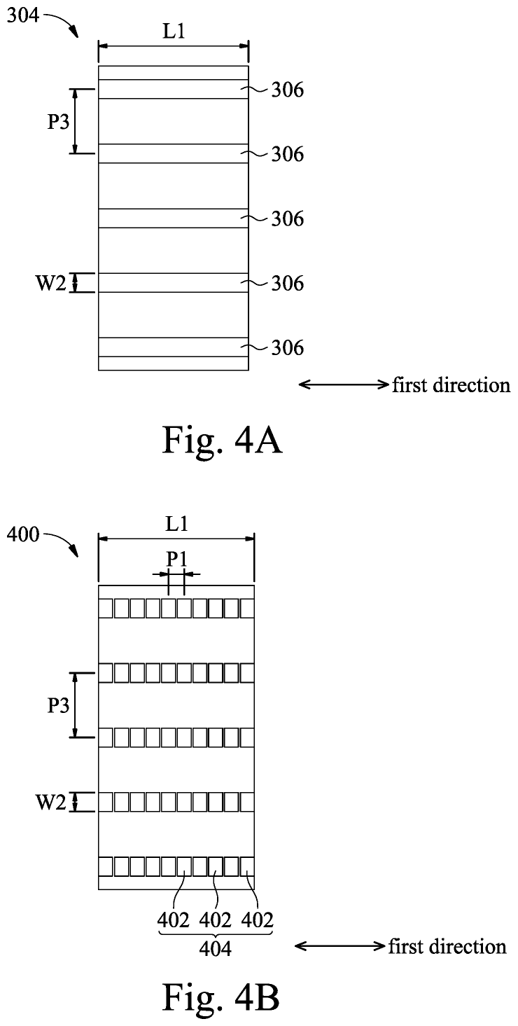

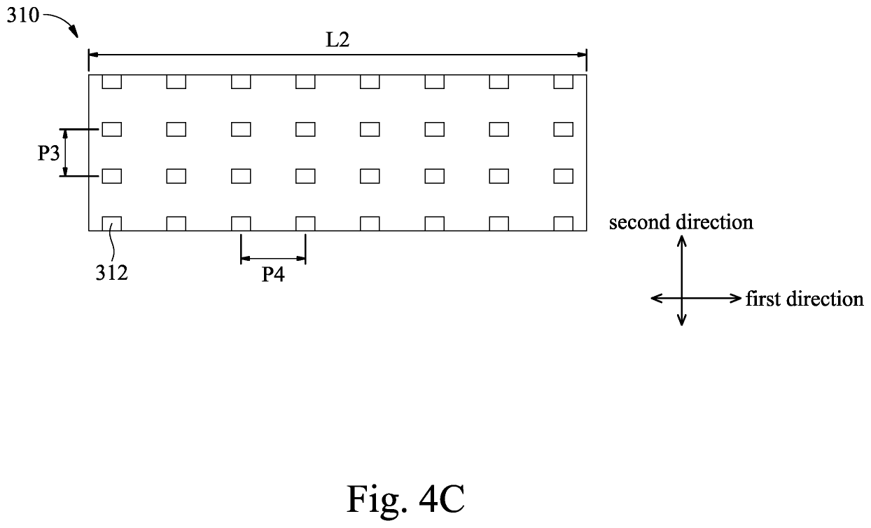

Next, referring to FIG. 3B, by rolling a first roller 304 to contact the micro devices 300 on the first substrate 302, the micro devices 300 are transferred to the first roller 304. Specifically, the first roller 304 includes contact line portions 306 axially arranged thereon. An adhesive layer 306a is coated on the surfaces of the contact line portions 306. As FIG. 3B is a side view in the first direction, referring to FIG. 4A, which is a side view in the second direction, FIG. 4A shows a plurality of contact line portions 306, and each of the contact line portions 306 is a continuous line. The pitch P3 of the contact line portions 306 is N times P2, namely, N times the predetermined value (N is a positive real number greater than or equal to 1). The width W2 of the contact line portion 306 may be greater than or equal to the width W1 of the micro device 300 to enhance the strength by which the contact line portions 306 pick up or adhere to the micro devices 300. In addition, the height H2 of the contact line portion 306 may be greater than or equal to the height H1 of the micro device 300 to enhance the operation quality at the moment that the contact line portions 306 pick up or adhere to the micro devices 300. Furthermore, the width L1 of the first roller 304 may be less than the width of the first substrate 302, and transfer of the micro devices 300 may be completed by repetitive picking and placing.

Further modifications may be made to the first roller 304. For example, in the roller 400 shown in FIG. 4B, a contact line portion 404 is formed of a plurality of first protrusions 402. The pitch of the first protrusions 402 is equal to the pitch P1 (i.e., the predetermined value) of the micro devices 300. In other words, when the roller 400 rolls in the first direction and contacts the micro devices 300, each of the micro devices 300 adheres to one of the first protrusions 402.

Referring to FIG. 3B, the adhesion force of the adhesive layer 306a is greater than the adhesion force of the adhesive layer 302a after being subjected to a light or heat stimulus, and the adhesion force may be an adhesive force, an electrostatic force, a pressure, or a Van der Waals force. For example, the adhesive layer 306a may use another adhesive material (e.g., a pressure-sensitive adhesive) having a viscosity operation window different from that of the adhesive layer 302a to pick up the micro devices 300 on the first substrate 302 by adhesion. In the second embodiment, the rolling speed of the first roller 304 matches the speed at which the first substrate 302 moves in the first direction. This makes it possible to manufacture using a production line.

After the micro devices 300 are transferred to (the contact line portions 306 of) the first roller 304, referring to FIG. 3C, the micro devices 300 of the first roller 304 are transferred to a second substrate 308 (a temporary substrate). An adhesive layer 308a is coated on the surface of the second substrate 308. The material of the second substrate 308 is selected, for example, to match the coefficient of thermal expansion (CTE) of the first substrate 302. In the present embodiment, the adhesion force of the adhesive layer 308a is greater than the adhesion force of the adhesive layer 306a, and the adhesion force may be an adhesive force, an electrostatic force, a pressure, or a Van der Waals force. For example, another adhesive material having a viscosity operation window different from that of the adhesive layer 306a may be used on the second substrate 308 as the adhesive layer 308a to pick up the micro devices 300 on the contact line portions 306 by adhesion. One example is a UV release film, which has an adhesive force before UV light irradiation greater than the adhesive force of the pressure-sensitive adhesive. In FIG. 3C, the pitch P1 in the second direction of the micro devices 300 transferred onto the second substrate 308 is the predetermined value, and the pitch P3 in the first direction is N times the predetermined value, P2. Therefore, in this stage, expansion of the pitch of the micro devices 300 by N times in the first direction is completed.

Next, the second substrate 308 is rotated by 90 degrees to obtain the result shown in FIG. 3D. Moreover, rotation of the second substrate 308 by 90 degrees may be performed by using a moving apparatus such as a carrier and a robotic arm (for example, using a combination of a rotating robot and a linear robot) and is not specifically limited herein.

Then, referring to FIG. 3E, by rolling a second roller 310 to contact the micro devices 300 on the second substrate 308, the micro devices 300 are transferred to the second roller 310. The second roller 310 includes a plurality of second protrusions 312. An adhesive layer 312a is coated on the surfaces of the second protrusions 312. In the side view in the first direction (see FIG. 4C), it is observed that the pitch P3 of the second protrusions 312 in the second direction is N times P2, and the pitch P4 of the second protrusions 312 in the first direction is M times P1, wherein M is a positive real number greater than or equal to 1, and M may be a value equal to N. Furthermore, the width L2 of the second roller 310 may be determined by the total length of the second substrate 308 in the first direction, or the same as L1 to transfer of the micro devices 300 by repetitive picking and placing. Since the pitches between the second protrusions 312 of the second roller 310 itself has been expanded N times and M times in both the first direction and the second direction, only those micro devices 300 having a pitch of P3 will be transferred onto the second protrusions 312.

In the present embodiment, the adhesion force of the adhesive layer 312a is greater than the adhesion force of the adhesive layer 308a after being subjected to a light or heat stimulus, and the adhesion force may be an adhesive force, an electrostatic force, a pressure, or a Van der Waals force. For example, the adhesive layer 312a may use another adhesive material having a viscosity operation window different from that of the adhesive material of the adhesive layer 308a to pick up the micro devices 300 on the second substrate 308 by adhesion. One example is a pressure-sensitive adhesive having an adhesive force between the adhesive forces of the UV release film before light irradiation (before transfer) and after light irradiation. Through light irradiation to the UV release film, the adhesiveness of the adhesive layer 308a is reduced.

After the micro devices 300 are transferred to (the second protrusions 312 of) the second roller 310, referring to FIG. 3F, the micro devices 300 on the second roller 310 are transferred to a third substrate 314, which may be a temporary substrate or a product substrate. An adhesive layer 314a is coated on the surface of the third substrate 314. If the third substrate 314 is a temporary substrate, the material is selected, for example, to match the coefficient of thermal expansion (CTE) of the first substrate 302. For example, the first substrate 302 and the third substrate 314 may be formed of the same material. Alternatively, the third substrate 314 is a product substrate having circuits and electrodes. In the present embodiment, the adhesion force of the adhesive layer 314a is greater than the adhesion force of the adhesive layer 312a, and the adhesion force may be an adhesive force, an electrostatic force, a pressure, or a Van der Waals force. For example, when the third substrate 314 is a product substrate having circuits and electrodes, the adhesive layer 314a may use an ACF or an SAP as the adhesive material to simultaneously achieve adhesion, electrical conduction, and self-assembly positioning. On the other hand, if the third substrate 314 is a temporary substrate, the UV release film may be used, and transfer to another product substrate may be performed in a subsequent process. For example, the micro devices 300 on the third substrate 314 may be first attached to a glass substrate, and a UV light is irradiated from the backside of the third substrate 314 to reduce the adhesiveness of the UV release film. Then, the third substrate 314 is peeled off.

In summary of the process of the second embodiment, the apparatus for implementing the second embodiment at least includes the first substrate 302, the first roller 304, the second substrate 308 (i.e., the temporary substrate), the moving apparatus (not shown), and the second roller 310. Table 2 shows material selections of the components in the exemplary solution where the transfer of the micro devices is controlled by the adhesive force. However, the disclosure is not limited thereto.

TABLE 2

| component | material | requirement |
|---|---|---|
| first substrate | non-deformable inorganic material, e.g. | reducing variations in |
| | glass, silicon wafer, quartz | position of micro |
| | | devices thereon resulting |
| | | from variations |
| | | in environmental temperature |
| | | or humidity |
| adhesive layer | UV release film manufactured by Nanya | adhesive force before de- |
| between first | Plastic corporation; glass adhesive force | adhesion being greater than |
| substrate and | before de-adhesion may be adjusted to | adhesive force after de- |
| micro devices | 200 gf/25 mm~2000 gf/25 mm, and | adhesion |
| | adhesion force to glass after de-adhesion | |
| | may be reduced to 30 gf/25 mm or below | |
| first roller | e.g. stainless steel, anodic aluminum | dimensionally stable material |
| | oxide | matching coefficient of |
| | | thermal expansion (CTE) of |
| | | first substrate |
| contactline | polydimethylsiloxane (PDMS) | elastomer |
| portions | (adhesive force: | |
| | 50 gf/25 mm~100 gf/25 mm) | |
| adhesive layer | oil-borne or water-borne acrylic | adhesive force being |
| on contact line | pressure-sensitive adhesive | between adhesive force of |
| portion | | UV release film before light |
| | | irradiation and after light |
| | | irradiation |
| second substrate | glass, quartz | transparent, dimensionally |
| | | stable |
| adhesive layer | UV release film as above | adhesive force being |
| on second | | between adhesion force of |
| substrate | | UV release film before light |
| | | irradiation and after light |
| | | irradiation |
| second roller | e.g. stainless steel, anodic aluminum | dimensionally stable material |
| | oxide | matching coefficient of |
| | | thermal expansion (CTE) of |
| | | second substrate |
| second | PDMS | elastomer |
| protrusions | | |
| adhesive layer | oil-borne or water-borne acrylic | adhesive force being |
| onsecond | pressure-sensitive adhesive | between adhesion force of |
| protrusions | | UV release film before light |
| | | irradiation and after light |
| | | irradiation |
| third substrate | glass, quartz | transparent, flexible, |
| | | dimensionally stable |
| | glass | transparent, dimensionally |
| | | stable |
| adhesive layer | UV release film as above | adhesive force before de- |
| on third | | adhesion being greater than |
| substrate | | adhesive force after de- |
| | | adhesion |
| | Anisotropic conductive film (ACF) | conductive adhesive having |
| | (peel strength at about 500 gf/25 mm) or | adhesive force adhesion |
| | Epowell AP series anisotropic | |
| | conductive paste (SAP) (peel strength at | |
| | about 4800 gf/25 mm) manufactured by | |
| | Sekisui Chemical Co., Ltd. | |

In summary of the above, the disclosure adopts the transfer technique of two-step rollers with the flat substrate to achieve pitch expansion and transfer of the micro devices in a simple and low-cost manner, which avoids the heavy time consumption of the picking/placing technique using a linear motion combination.

The adhesive layers of different properties were compared. The Young's modulus of the surface of the adhesive layer was measured by atomic force microscope (AFM). The adhesive layer was attached to a glass substrate to measure the adhesion force of the adhesive force to the glass substrate. The adhesive layer was then irradiated by UV to be cured for measuring the adhesion force of the adhesive layer to the glass substrate.

A testing substrate was provided, which included a plurality of micro structures on its surface. The testing substrate is formed by following steps: depositing gallium nitride layer on a sapphire substrate, and pattering the gallium nitride layer by lithography and etching, thereby forming an array of plurality of gallium nitride micro structures. Each of the gallium nitride micro structures had a length of 140 μm, a width of 90 μm, and a thickness of 6 μm. The adjacent gallium nitride micro structures were separated by a gap having a depth of 6 μm and a width of 10 μm. The structure depth was measured by surface profilometer (Alpha-step) as 5.27 μm. The adhesive layer of the adhesive structure was attached to the micro structures of the testing substrate by a 2 kg roller, and a 3M double sided tape (PN. 8333, having an adhesive force greater than 1418 gf/20 mm) was used to check whether the micro structures could be removed from the adhesive layer. The adhesive layer was then irradiated by UV to perform de-adhesion (photo curing), and the 3M double sided tape (PN. 8333, having an adhesive force greater than 1418 gf/20 mm) was used to check whether the micro structures could be removed from the adhesive layer. In addition, after removing the micro structures on the testing substrate from the adhesive layer, the surface of the adhesive layer after de-adhesion was analyzed by surface profilometer (Alpha-step) to measure the structure depth of the surface of the adhesive layer. In general, if the structure depth was deeper, the depth of the micro structures sunk into the adhesive layer would be deeper, and it will be more difficult to remove the micro structures from the adhesive layer. Ideally, the micro structures on the testing substrate should not be removed from the adhesive layer before de-adhesion, and the micro structures should be removed from the adhesive layer after de-adhesion, and the micro structures were free of adhesive residue. The measurement results are tabulated in Table 3.

TABLE 3

| | Comparative | Example | Example | Example | Example | Comparative |
|---|---|---|---|---|---|---|
| sample | Example 1 | 1 | 2 | 3 | 4 | Example 2 |
| adhesive layer thickness | 5 ± 2 μm | 5 ± 2 μm | 5 ± 2 μm | 5 ± 2 μm | 5 ± 2 μm | 5 ± 2 μm |
| (μm) | | | | | | |
| Young’s modulus of | 4.2 | 7.8 | 9.5 | 9.9 | 12.16 | 14.1 |
| adhesive layer (MPa) | | | | | | |
| adhesive force of | 1107 | 780.6 | 813.380 | 873.7 | 220 | 418.8 |
| adhesive layer before UV | | | | | | |
| irradiation (gf/25 mm) | | | | | | |
| adhesive force of | 71.25 | 17.76 | 14.9610 | 15.4 | 5.8 | 11.89 |
| adhesive layer after UV | | | | | | |
| irradiation (gf/25 mm) | | | | | | |

attaching process evaluation

| | | | | | | |
|---|---|---|---|---|---|---|
| structure removal before | X | X | X | X | X | ◯ |
| UV irradiation | | | | | | |
| structure removal after | X | ◯ | ◯ | ◯ | ◯ | ◯ |
| UV irradiation | | | | | | |
| surface structure depth of | 5.67 | 0.47 | 1.240 | 0.804 | 0.88 | 0.12 |
| adhesive layer after | | | | | | |
| structure removal (um) | | | | | | |
| depth after structure | 1.08 | 0.09 | 0.24 | 0.15 | 0.17 | 0.02 |
| removal/height of | | | | | | |
| transferred micro | | | | | | |
| structure | | | | | | |

It will be apparent to those skilled in the art that various modifications and variations can be made to the disclosed methods and materials. It is intended that the specification and examples be considered as exemplary only, with the true scope of the disclosure being indicated by the following claims and their equivalents.

What is claimed is:

1. A method of transferring devices, comprising:
providing a first substrate with a plurality of micro devices having pitches being a predetermined value in a first direction and a second direction, wherein the first substrate and the micro devices have a first adhesive layer therebetween;
transferring the micro devices to a second substrate by contacting the second substrate with the micro devices on the first substrate and de-adhering the first adhesive layer, wherein the surface of the second substrate has a second adhesive layer,
wherein the first adhesive layer before de-adhesion has a Young's modulus of 5 MPa to 14 MPa and an adhesive force to glass of 200 gf/25 mm to 2000 gf/25 mm.

2. The method as claimed in claim 1, wherein the first adhesive layer after de-adhesion has an adhesive force to glass of less than or equal to 30 gf/25 mm.

3. The method as claimed in claim 1, wherein the first adhesive layer after de-adhesion has an adhesive force to glass of less than or equal to 20 gf/25 mm.

4. The method as claimed in claim 1, wherein the first adhesive layer after de-adhesion has an adhesive force to glass of less than or equal to 10 gf/25 mm.

5. The method as claimed in claim 1, wherein the first adhesive layer has a thickness of less than 10 μm.

6. The method as claimed in claim 1, wherein the first adhesive layer has a thickness of 1 μm to 9 μm.

7. The method as claimed in claim 1, wherein the first adhesive layer after transferring the micro devices has a depth after structure removal, and the depth after structure removal and a structure height of the micro devices have a height ratio of 1:1 to 0.01:1.

8. The method as claimed in claim 1, wherein the first adhesive layer after transferring the micro devices has a depth after structure removal, and the depth after structure removal and the structure height of the micro devices have a height ratio of 0.8:1 to 0.05:1.
